(19) United States
(12) Patent Application Publication
(10) Pub. No.: US 2016/0336543 A1
(43) Pub. Date: Nov. 17, 2016

(54) ADHESIVE STORAGE TANK, ADHESIVE SPREADER, AND METHOD OF MANUFACTURING ADHESIVE

(71) Applicants: BOE TECHNOLOGY GROUP CO., LTD., Beijing (CN); HEFEI XINSHENG OPTOELECTRONICS TECHNOLOGY CO.,LTD., Hefei Anhui (CN)

(72) Inventors: Wei Quan, Beijing (CN); Chia-Hao Chang, Beijing (CN)

(21) Appl. No.: 14/906,773

(22) PCT Filed: Jun. 19, 2015
(86) PCT No.: PCT/CN2015/081948

§ 371 Date: Jan. 21, 2016

(30) Foreign Application Priority Data
Dec. 30, 2014 (CN) 201410843221.5

(51) Int. Cl. H01L 51/56; B01D 19/00; H01L 51/52; B05C 11/11

(52) U.S. Cl. CPC H01L 51/56; B05C 11/11; B01D 19/0036; H01L 51/5246; H01L 51/5259

(57) ABSTRACT

An adhesive storage tank includes: an accommodation part for accommodating an adhesive; a stirring device disposed in the accommodation part; and a vacuum device for suctioning gas from the accommodation part.

### BACKGROUND OF THE INVENTION

1. Field of the Invention

Embodiments of the present invention relates to an adhesive spreader, an adhesive storage tank, and a method of manufacturing an adhesive.

2. Description of the Related Art

In conventional packaging of an organic light-emitting device (OLED), generally, the packaging is carried out by curing an epoxy resin by means of ultraviolet radiation. During the packaging of the OLED, it is often necessary to apply an epoxy resin adhesive to a large range to stick substrates together. In order to improve production efficiency, an adhesive spreader is usually used to carry out the application. Generally, the adhesive spreader or an adhesive spreading assembly comprises an adhesive spreading needle tubing and an adhesive storage tank.

At present, an adhesive needs to be de-aerated before being placed into the adhesive storage tank. However, due to reasons such as de-aeration effect and a long period of time for placing a de-aerated adhesive into the adhesive storage tank, bubbles will be easily generated in the adhesive, thereby adversely affecting packaging effect. As a result, muras, dark spots and the like will appear in the packaged devices.

### SUMMARY OF THE INVENTION

Embodiments of the present invention provide an adhesive storage tank comprising: an accommodation part for accommodating an adhesive; a stirring device disposed in the accommodation part; and a vacuum device for suctioning gas from the accommodation part.

Embodiments of the present invention provide an adhesive spreader comprising an adhesive spreading part and the abovementioned adhesive storage tank.

Embodiments of the present invention provide a method of manufacturing an adhesive comprising steps of: placing an adhesive into an accommodation part of an adhesive storage tank; and suctioning gas from the accommodation part such that an inside of the accommodation part is maintained in a negative-pressure state, while stirring the adhesive, thereby de-aerating the adhesive.

### BRIEF DESCRIPTION OF THE DRAWINGS

The above and/or other aspects and advantages of the present invention will be apparent and more readily appreciated from the following description of embodiments taken in conjunction with the accompanying drawings, in which:

FIG. 1 is a view showing a structure of an adhesive storage tank in an adhesive spreader according to an embodiment of the present invention.

### DETAILED DESCRIPTION OF THE EMBODIMENTS

A further description of the invention will be made in detail as below with reference to embodiments of the present invention taken in conjunction with the accompanying drawings. The following embodiments are intended to explain the present invention and the present invention should not be construed as being limited to the embodiment set forth herein.

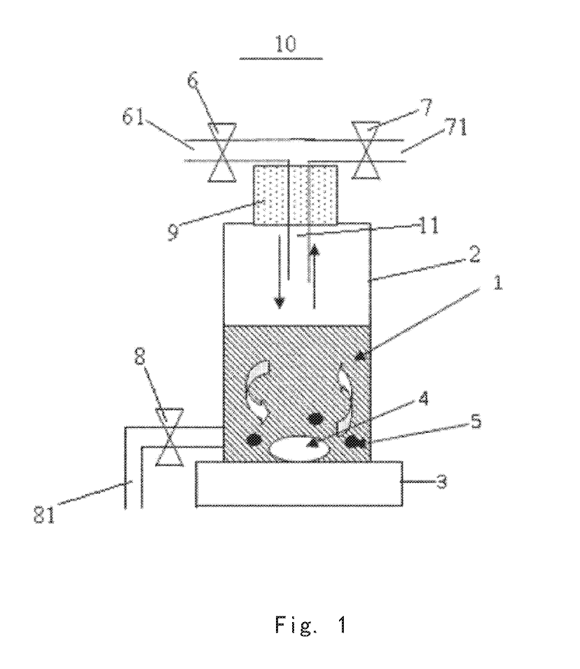

Technical solutions of the present invention will be further specifically described as below by means of embodiments in conjunction with FIG. 1.

Technology of application of an adhesive is one of main manners in which semiconductor devices such as OLEDs are packaged at present. The adhesive may comprise a seal adhesive and a filling adhesive. However, the two types of adhesives probably both contain bubbles so that muras and the like will easily occur in corresponding packaged devices, thereby adversely affecting quality of the corresponding devices.

An adhesive spreader comprises an adhesive storage tank and an adhesive spreading part (not shown) cooperating with the adhesive storage tank. Specifically, the adhesive spreading part may comprise parts that can apply an adhesive, such as an adhesive spreading needle tubing. The adhesive spreading needle tubing is connected with the adhesive storage tank.

As shown in FIG. 1, the adhesive storage tank 10 comprises: an accommodation part 2 for accommodating an adhesive 1; a stirring device 3, 4 disposed in the accommodation part; and a vacuum device 71 for suctioning gas from the accommodation part. The stirring device may comprise: a magnetic stirrer 3 disposed at a bottom of the accommodation part 2; and a magnetic stirring piece 4 disposed inside the accommodation part 2 and placed on the magnetic stirrer 3. The stirring device may be any of appropriate stirring devices.

As shown in FIG. 1, the accommodation part 2 is a generally cylindrical chamber formed by a body of the adhesive storage tank 10. The adhesive storage tank may further comprise an adhesive discharge pipe 81 for connecting the accommodation part 2 with an adhesive spreading part for applying an adhesive. Through the adhesive discharge pipe 81, the chamber is connected with the adhesive spreading needle tubing disposed outside the adhesive storage tank 10, so that the adhesive can be injected into the adhesive spreading needle tubing, thereby applying the adhesive.

At least one magnetic stirring piece 4 may be disposed inside the accommodation part 2 and placed on the magnetic stirrer 3. The magnetic stirrer 3 is used to stir the adhesive 1, thereby removing bubbles that are included in the adhesive. In an embodiment, the adhesive 1 is a filling adhesive or may also be a seal adhesive, and the number of the magnetic stirring pieces 4 can be set according to requirements.

According to embodiments of the present invention, the adhesive storage tank may comprise a heating device for heating the adhesive in the accommodation part. For example, the magnetic stirrer 3 may be a heated magnetic stirrer. In other words, the magnetic stirrer 3 also has a heating function so that it can heat the adhesive in the adhesive storage tank 4, thereby increasing flowability of the adhesive. Of course, the magnetic stirrer 3 need not be limited to the abovementioned example as long as it has the heating function. The flowability of the adhesive 1 can be increased by heating the adhesive at a certain temperature, thereby facilitating a discharge of the bubbles from the adhesive 1. However, since adhesives usually used are of a thermosetting type, a heating temperature of the adhesive 1 is controlled below 40° C., i.e., within a range of 0-40° C. in order to avoid an excessive heating temperature. Of course, an appropriate temperature of heating an adhesive actually used can also be selected according to a type or property of the adhesive.

In another example, in order to reduce a risk of damage to devices to be packaged due to moisture, an appropriate number of molecular sieves 5 may also be disposed in the accommodation part 2 to absorb moisture remaining in the adhesive 1 or entering into the adhesive 1 due to carelessness. Of course, any type of molecular sieves may be selected as long as molecular sieves can function to absorb the abovementioned moisture.

According to an embodiment of the present invention, in order to achieve de-aerating and injecting of the adhesive 1 in the accommodation part 2, the adhesive storage tank further comprises a pressurization device for pressurizing an inside of the accommodation part 2 in addition to a vacuum device and an adhesive discharge pipe 81 for connecting the accommodation part 2 with an adhesive spreading part for applying an adhesive. The pressurization device may comprise a pressurization pipe 61 connected with the accommodation part 2 and a pressure source (such as a pressurized gas source), and the vacuum device may comprise a gas suctioning pipe 71 connected with the accommodation part 2 and a vacuum source (such as a vacuum pump). Specifically, the accommodation part 2 is further provided with the pressurization pipe 61, the gas suctioning pipe 71, and the adhesive discharge pipe 81. In the example shown in FIG. 1, both the pressurization pipe 61 and the gas suctioning pipe 71 are disposed at a top of the accommodation part 2, and the adhesive discharge pipe 81 is disposed at a side surface of a lower portion of the accommodation part 2. Of course, positions of the pressurization pipe 61, the gas suctioning pipe 71 and the adhesive discharge pipe 81 need not be limited to the situation shown in the figure as long as the abovementioned object can be achieved. For example, both the pressurization pipe 61 and the gas suctioning pipe 71 are disposed at a side surface of an upper portion of the accommodation part 2.

As shown in FIG. 1, according to embodiments of the present invention, the adhesive storage tank further comprises: a pressurization valve 6 disposed on the pressurization pipe 61 and configured to switch on and shut off the pressurization pipe 61, and a gas suctioning valve 7 disposed on the gas suctioning pipe 71 and configured to switch on and shut off the gas suctioning pipe 71. The adhesive storage tank may further comprise: a common pipe 11 connected with the pressurization pipe 61 and the gas suctioning pipe 71 and located downstream of the pressurization valve 6 and the gas suctioning valve 7. The adhesive storage tank may further comprise a tank cover 9 which seals a top of the accommodation part 2 and through which the common pipe 11 is inserted in the accommodation part 2.

In the example shown in FIG. 1, the pressurization pipe 61 and the gas suctioning pipe 71 join above the tank cover 9 of the adhesive storage tank 10, and are inserted in the accommodation part 2 by means of the single common pipe 11 through the tank cover 9. The pressurization pipe 61 and the gas suctioning pipe 71 are provided with the pressurization valve 6 and the gas suctioning valve 7, respectively. In this way, when the respective valves of the pressurization pipe 61 and the gas suctioning pipe 71 are in an switch-on state, the pressurization pipe 61 and the gas suctioning pipe 71 can perform pressurizing and suctioning through the pipe 11, respectively (as shown by the arrows in the figure).

Accordingly, the adhesive discharge pipe 81 is disposed at the lower portion of the accommodation part 2 and, specifically at a left side surface of the lower portion of the accommodation part 2 as shown in the figure. The adhesive discharge pipe 81 is provided with an adhesive discharge port valve 8 so as to inject the adhesive 1 into the adhesive spreading needle tubing.

As described above, the adhesive storage tank 10 may be used in packaging of semiconductor devices such as OLEDs.

In another embodiment of the present invention, there is also provided an adhesive spreader comprising an adhesive spreading part such as an adhesive spreading needle tubing and the abovementioned adhesive storage tank.

In still another embodiment of the present invention, there is also provided a method of manufacturing an adhesive, which may be performed by means of the abovementioned adhesive storage tank or adhesive spreader.

The method of manufacturing an adhesive comprises: placing an adhesive into an accommodation part of an adhesive storage tank; and suctioning gas from the accommodation part such that an inside of the accommodation part is maintained in a negative-pressure state, while stirring the adhesive, thereby de-aerating the adhesive. The method of manufacturing an adhesive may further comprise stopping suctioning gas from the accommodation part, and pumping gas into the accommodation part to pressurize the inside of the accommodation part, thereby discharging the adhesive from the accommodation part into an adhesive spreading part.

According to an example of the present invention, referring to FIG. 1, the method comprises steps of:

placing a prepared adhesive 1 into the accommodation part 2 of the abovementioned adhesive storage tank 10;

while a pressurization pipe 61 and an adhesive discharge pipe 81 of the adhesive storage tank 10 are both maintained in a shut-off state, switching on a gas suctioning pipe 7 of the adhesive storage tank 10 while stirring the adhesive, thereby de-aerating the adhesive; and

after completing the de-aerating, shutting off the gas suctioning pipe 71 and switching on the pressurization pipe 61 and the adhesive discharge pipe 81 to inject the adhesive into an adhesive spreading part connected with the adhesive storage tank 10.

According to an embodiment of the present invention, the adhesive 1 in the accommodation part 2 can be de-aerated by heating and stirring the adhesive while the gas suctioning pipe 71 (or the gas suctioning valve 7) is switched on. The flowability of the adhesive 1 can be increased by heating the adhesive at a certain temperature, thereby facilitating a discharge of the bubbles from the adhesive 1.

In addition, when the adhesive needs to be injected into the adhesive spreading needle tubing, the gas suctioning pipe 71 (or the gas suctioning valve 7) is shut off and the pressurization pipe 61 (the pressurization valve 6) and the adhesive discharge pipe 81 (or the adhesive discharge port valve 8) are switched on, so that the adhesive can easily flow out. This is because the adhesive 1 has a better flowability at a certain temperature so that the adhesive can be injected into the adhesive spreading needle tubing better.

With the adhesive storage tank, the adhesive spreader, and the method of manufacturing an adhesive according to the embodiments of the present invention, at least an amount of bubbles in an adhesive will be reduced and adhesive spreading effect will be improved.

With the adhesive storage tank, the adhesive spreader, and the method of manufacturing an adhesive according to the embodiments of the present invention, at least one of the following advantages can be achieved:

(1) the amount of bubbles generated during application of the adhesive is reduced since the de-aerating of the adhesive is completed inside the adhesive spreader; in other words, influence of bubbles on devices to be packaged is reduced since the adhesive storage tank has the de-aerating function;

(2) corresponding equipment and human investment can be decreased since the de-aerating function is combined into the adhesive spreading apparatus;

(3) outputting and de-aerating functions of the adhesive are improved since the adhesive storage tank has the heating function so that the flowability of the adhesive is increased;

(4) the de-aerating effect is retained to the fullest extent since an interval between the de-aerating of the adhesive and the use of the adhesive is shortened since the de-aerated adhesive can be used soon; and

(5) a risk of damage to OLEDs due to moisture is reduced since moisture remaining in the adhesive can be absorbed by the molecular sieve.

The above embodiments are only used to explain the present invention, and should not be construed to limit the present invention. It will be understood by those skilled in the art that various changes and modifications may be made therein without departing from the spirit of the present invention, the scope of which is defined in the appended claims and their equivalents.

1. An adhesive storage tank comprising:
an accommodation part for accommodating an adhesive;
a stirring device disposed in the accommodation part; and
a vacuum device for suctioning gas from the accommodation part.

2. The adhesive storage tank of claim 1, wherein:
the stirring device comprises:
a magnetic stirrer disposed at a bottom of the accommodation part; and
a magnetic stirring piece disposed inside the accommodation part and placed on the magnetic stirrer.

3. The adhesive storage tank of claim 1, further comprising:
a heating device for heating the adhesive in the accommodation part.

4. The adhesive storage tank of claim 3, wherein:
the adhesive is of a thermosetting type, and a temperature of heating the adhesive by the heating device is controlled within a range of 0-40° C.

5. The adhesive storage tank of claim 1, wherein:
the vacuum device comprises a gas suctioning pipe connected with the accommodation part.

6. The adhesive storage tank of claim 1, further comprising:
a pressurization device for pressurizing an inside of the accommodation part; and
an adhesive discharge pipe for connecting the accommodation part with an adhesive spreading part for applying an adhesive.

7. The adhesive storage tank of claim 5, further comprising:
a pressurization device for pressurizing an inside of the accommodation part; and
an adhesive discharge pipe for connecting the accommodation part with an adhesive spreading part for applying an adhesive.

8. The adhesive storage tank of claim 7, wherein:
the pressurization device comprises a pressurization pipe connected with the accommodation part.

9. The adhesive storage tank of claim 8, further comprising:
a pressurization valve disposed on the pressurization pipe and configured to switch on and shut off the pressurization pipe, and a gas suctioning valve disposed on the gas suctioning pipe and configured to switch on and shut off the gas suctioning pipe.

10. The adhesive storage tank of claim 9, further comprising:
a common pipe connected with the pressurization pipe and the gas suctioning pipe and located downstream of the pressurization valve and the gas suctioning valve.

11. The adhesive storage tank of claim 10, further comprising:
a tank cover which seals a top of the accommodation part and through which the common pipe is inserted in the accommodation part.

12. The adhesive storage tank of claim 1, further comprising:
a molecular sieve disposed within the accommodation part.

13. The adhesive storage tank of claim 6, wherein:
the adhesive discharge pipe is disposed at a lower portion of the accommodation part and is provided with an adhesive discharge port valve.

14. An adhesive spreader comprising:
an adhesive spreading part and the adhesive storage tank of claim 1.

15. A method of manufacturing an adhesive, comprising steps of:
placing an adhesive into an accommodation part of an adhesive storage tank; and
suctioning gas from the accommodation part such that an inside of the accommodation part is maintained in a negative-pressure state, while stirring the adhesive, thereby de-aerating the adhesive.

16. The method of claim 15, further comprising:
stopping suctioning gas from the accommodation part, and pumping gas into the accommodation part to pressurize the inside of the accommodation part so as to discharge the adhesive from the accommodation part into an adhesive spreading part.

17. The method of claim 16, wherein:
during the de-aerating, the adhesive is also heated at a temperature which is controlled within a range of 0-40° C.

18. The adhesive storage tank of claim 2, further comprising:
a pressurization device for pressurizing an inside of the accommodation part; and
an adhesive discharge pipe for connecting the accommodation part with an adhesive spreading part for with an adhesive spreading part for applying an adhesive, wherein:
the vacuum device comprises a gas suctioning pipe connected with the accommodation part; and
the pressurization device comprises a pressurization pipe connected with the accommodation part.

19. The adhesive storage tank of claim 18, further comprising:
a common pipe connected with the pressurization pipe and the gas suctioning.

20. The adhesive storage tank of claim 19, further comprising:
a tank cover which seals a top of the accommodation part and through which the common pipe is inserted in the accommodation part.
